(19) United States
(12) Patent Application Publication
(10) Pub. No.: US 2006/0220120 A1
(43) Pub. Date: Oct. 5, 2006

(54) High voltage LDMOS device with counter doping

(75) Inventor: Andrew Edward Horch, Seattle, WA (US)

Correspondence Address: MERCHANT & GOULD PC, P.O. BOX 2903, MINNEAPOLIS, MN, 55402-0903, US

(73) Assignee: IMPINJ, INC., Seattle, WA (US)

(21) Appl. No.: 11/096,611

(22) Filed: Mar. 31, 2005

(51) Int. Cl. H01L 29/76

(52) U.S. Cl. 257/341

(57) ABSTRACT

LDMOS structures and methods for fabricating them includes a counter dopant implant region in a drain well. According to another aspect, an LDMOS device includes a graded junction region in the LDMOS device's channel region. The counter dopant implant region may extend from the drain portion into the graded junction region. The counter dopant implant region can be formed using an implantation process that is already part of a standard MOS fabrication process. For example, in one embodiment, an implantation process that is used to adjust the threshold voltage (Vt) is used to form the counter doped region in the channel region of the LDMOS device.

### RELATED APPLICATIONS

This application is related to commonly-assigned U.S. patent application Ser. No. 10/______ entitled “GRADED JUNCTION HIGH-VOLTAGE MOSFET IN STANDARD LOGIC CMOS” by Bin Wang, filed Jul. 2, 2004.

### BACKGROUND

Some MOS (metal-oxide-semiconductor) integrated circuits (ICs) use relatively low voltages for operating standard MOS devices and relatively high voltages for other special uses such as, for example, programming voltages for non-volatile memory circuits, input/output (I/O) drivers, etc. However, standard low voltage MOS devices may be damaged by the high voltages. One approach to this scenario is to use laterally diffused MOS (LDMOS) devices for the high voltage sub-circuits of the ICs. LDMOS device fabrication can be relatively easily incorporated into standard MOS fabrication processes, which is highly desirable in many applications.

However, as performance and integration demands of MOS devices increase, there is a trend toward increasing well doping levels and/or reducing the thickness of the gate oxides. These process changes tend to negatively influence the performance of the LDMOS devices. Maintaining the performance of the LDMOS devices may require additional process steps that are not used in standard MOS processes or using existing steps in the formation of additional devices the steps were not originally intended for.

### SUMMARY

In accordance with aspects of various embodiments, provided are LDMOS structures and methods for fabricating the same. According to one aspect, a laterally diffused drain portion of a LDMOS device includes a counter dopant implant region. This counter dopant implant region can cause an increase in resistance in the channel, source or drain region (in one embodiment the counter dopant region is in the drain), which can increase the voltage drop between the drain and gate or between the drain and a p/n junction between two wells of the LDMOS device. Such an increased voltage drop can reduce the stress to the gate oxide. In addition, such an increased voltage drop can reduce the reverse bias peak electric field experienced by the p/n junction, which in turn can decrease the risk of junction breakdown. The counter doping can either grade the drain/channel junction or cause the drain channel junction to be below the surface of the silicon substrate, both of these will increase the gate assisted diode breakdown voltage of the junction.

According to another aspect, the LDMOS device includes a graded junction region in the LDMOS device's drain/channel junction. In some embodiments, the counter dopant implant region can extend from the drain portion into the graded junction region. The graded junction can also increase the reverse bias diode depletion width for a given voltage, this increases the reverse bias diode breakdown voltage.

According to still another aspect, the counter dopant implant region is formed using an implantation process that is already part of a standard MOS fabrication process. For example, in one embodiment, an implantation process that is used to adjust the threshold voltage (Vt) of a device designed to operate at a significantly lower voltage is used to form the counter doped region in the channel region of the LDMOS device. This Vt adjust implant is common in dual gate oxide processes used to fabricate standard low voltage MOS devices and further, is typically separate or in addition to the implants used to form the wells. This aspect can allow the LDMOS device to be fabricated without adding any additional process steps to a standard MOS process.

### BRIEF DESCRIPTION OF THE DRAWINGS

Non-limiting and non-exhaustive embodiments are described with reference to the following figures, wherein like reference numerals refer to like parts throughout the various views unless otherwise specified. Also, the diagrams are for illustrative purposes and are generally not to scale.

FIGS. 1-4 are cross-sectional diagrams illustrating various stages in the fabrication of a LDMOS device according to one embodiment.

FIGS. 5-8 are cross-sectional diagrams illustrating various stages in the fabrication of a graded-junction LDMOS device according to one embodiment.

FIG. 9 is a cross-sectional diagram illustrating a stage in the fabrication of a LDMOS device according to another embodiment.

FIG. 10 is a cross-sectional diagram illustrating a stage in the fabrication of a LDMOS device according to yet another embodiment.

FIG. 11 is a cross-sectional diagram illustrating a stage in the fabrication of a LDMOS device without an isolator in the drain well, according to one embodiment.

### DETAILED DESCRIPTION OF ILLUSTRATED EMBODIMENTS

Various embodiments are described more fully below with reference to the accompanying drawings, which form a part hereof, and which show specific exemplary embodiments for practicing the invention. However, embodiments may be implemented in many different forms and should not be construed as limited to the embodiments set forth herein; rather, these embodiments are provided so that this disclosure will be thorough and complete, and will fully convey the scope of the invention to those skilled in the art. Embodiments of the present invention may be practiced as methods, systems or devices. The following detailed description is, therefore, not to be taken in a limiting sense.

Throughout the specification and claims, the following terms take at least the meanings explicitly associated herein, unless the context clearly dictates otherwise. The meanings identified below are not intended to limit the terms, but merely provide illustrative examples for the terms. The meaning of “a,” “an,” and “the” includes plural reference, the meaning of “in” includes “in” and “on.” The term “connected” means a direct electrical connection between the items connected, without any intermediate devices. The term “coupled” means either a direct electrical connection between the items connected or an indirect connection through one or more passive or active intermediary devices. The term “circuit” means either a single component or a multiplicity of components, either active and/or passive, that are coupled together to provide a desired function. The term “signal” means at least one current, voltage, charge, temperature, data, or other measurable quantity.

In the interest of clarity, not all of the routine features of the implementations and fabrication process are shown and described. Further, as used herein, the symbol n+indicates an n-doped semiconductor material typically having a doping level of n-type dopants on the order of 10²⁰ per cubic centimeter. The symbol n− indicates an n-doped semiconductor material typically having a doping level on the order of 10¹⁸ per cubic centimeter for n− wells and on the order of 10¹⁷ per cubic centimeter for n− substrate material. The symbol p+ indicates a p-doped semiconductor material typically having a doping level of p-type dopants on the order of 10²⁰ per cubic centimeter. The symbol p− indicates a p-doped semiconductor material typically having a doping level on the order of 10¹⁷ per cubic centimeter for p− wells and on the order of 10¹⁵ per cubic centimeter for p− substrate material.

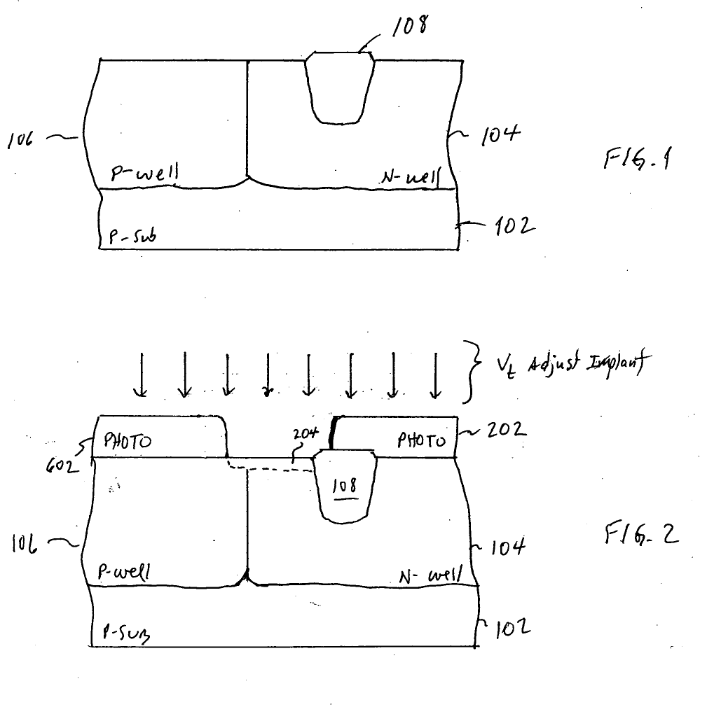

FIG. 1 illustrates a stage in the fabrication process of a LDMOS device, according to one embodiment. In this exemplary embodiment, the LDMOS device is a n-channel device to be embedded in a standard logic CMOS IC fabrication process. Standard structures such as a body terminal for substrate back biasing are omitted in the interest of clarity.

Starting with a p− substrate 102, a n− well 104 and a p− well 106 are formed in substrate 102. In this embodiment, wells 104 and 106 are formed in substrate 102 using standard processes for low-voltage MOS devices. For example, standard photolithography processes may be used to form implant masks defining the wells. After the implants, a thermal drive-in process may be used to diffuse the implanted dopants further into the substrate to form the wells.

In this embodiment, an isolator 108 is formed in n− well 104. In this embodiment, isolator 108 is formed using a suitable shallow trench isolation (STI) process before n− well 104 and p− well 106 are formed in substrate 102. In other embodiments, isolator 108 may be a field oxide region formed using suitable processes such as a local oxidation of silicon (LOCOS) process. In general, such an isolator is formed in the well in which the drain of the LDMOS device will be formed. This LDMOS structure provides a relatively long drain region with a doping level significantly below the level of the logic FET source/drain extension regions, that is used to: (a) increase the IR drop from the drain contact to the diode junction to reduce stress on the gate oxide; and (b) reduce the risk of gated diode breakdown, when subjected to relatively high voltages. Accordingly, because the LDMOS device is a n-channel device in this exemplary embodiment, isolator 108 is formed in n− well 104. Conversely, in p-channel embodiments, the isolator would be formed in a p− well. For n-substrate processes, all the polarities are reversed.

FIG. 2 illustrates a subsequent stage in this exemplary fabrication process of a LDMOS device. Using standard photolithography processes, a photomask 202 is formed over wells 104 and 106, defining a region adjacent to isolator 108 to receive a surface implant. In general, the dopants used in this implant are of complementary or opposite conductivity type relative to the well in which the isolator resides, the same conductivity type as the channel region. Accordingly, this implant is referred to herein as a counter dopant implant and the implant region is referred to herein as the counter dopant implant region. Consequently, in this exemplary embodiment, p-type dopants are used in this counter dopant implant and form a counter dopant implant region 204. In this exemplary embodiment, counter dopant implant region 204 is defined by photomask 202 in a non-self aligned process. As can be seen in FIG. 2, counter dopant implant region 204 extends from isolator 108 partially into p− well 106. Further, in this exemplary embodiment, the implant causes the portion of counter dopant implant region 204 that is disposed in n− well 104 to have a net p-type polarity (i.e., this portion is counter doped).

In operation, as the gate voltage exceeds the threshold voltage of the LDMOS device, the portion of counter dopant implant region 204 within n− well 104 will start to deplete, effectively increasing the dielectric thickness between the gate and n− well when the device turns off. This effect advantageously serves to reduce the stress on the gate oxide (formed at a later stage). In addition, the portion of counter dopant region 204 within n− well 104 also pushes the p/n junction formed between p− well 106 and n− well 104 down away from the gate. This effect can advantageously reduce the effect of the gate voltage on the p/n junction, thereby reducing the risk ofjunction diode breakdown (also referred to as gated diode breakdown).

In other embodiments, the counter dopant implant region need not extend into the channel region (i.e., p− well 106 in this exemplary embodiment). In still other embodiments, the counter dopant implant region may extend so that it will be adjacent to the subsequently formed source contact region of the LDMOS device.

Further, in other embodiments, the counter dopant implant may cause the portion of the counter dopant implant region residing in the “drain” well (i.e., n− well 104 in this exemplary embodiment) to have a reduced net dopant concentration that does cause the portion to be counter doped. For example, if the “drain” well is an n− well, then in such an embodiment the portion of the counter dopant implant region (which may be the entire counter dopant implant region in some embodiments) remains of n-type conductivity, but of a lower net concentration of n-type dopants than the n− well.

Further, in accordance with this embodiment, the counter dopant implant is the same implant that is used to adjust the threshold voltage (Vt) of the standard low-voltage devices in the IC. Photomask 202 is formed in the same photomask processes used to form the Vt adjust implant mask. Thus, in this embodiment, no additional implants or photolithography processes are needed.

FIG. 3 illustrates another stage in this exemplary fabrication process of a LDMOS device. In this exemplary process, standard processes used in forming a gate oxide, a gate, and end caps for the low voltage MOS devices are also used to form a gate oxide 302, a gate 304, and end caps 306 of the LDMOS device. Thus, no additional steps are needed to form these structures for the LDMOS device. For example, gate oxide 302 may be deposited or grown using any suitable MOS processes; gate 304 may be formed using suitable polysilicon or doped polysilicon deposition processes, metal deposition processes, etc.; and end caps 306 may be formed by suitable dielectric deposition and dielectric-selective anisotropic etching processes.

FIG. 4 illustrates another stage in this exemplary fabrication process of a LDMOS device. In this exemplary process, n+regions 402 and 402A are formed in wells 106 and 104, respectively. These n+regions serve as source/drain contact regions for subsequent metal (or other conductor) deposition processes. In one embodiment, standard n-type dopant implantation processes are used to form n+regions 402 and 402A at the same time that the source/drain regions of the low voltage MOS devices of the IC are formed. Thus, no additional process steps are needed to form the source/drain regions of the LDMOS device. In this embodiment, a lightly doped drain (LDD) implant is also performed that results in the shallow source extension of n+ region 402. Additional processes are then performed to form interconnect between the LDMOS device to other devices or structures in the IC.

This exemplary fabrication process may be implemented in other MOS process such as, for example, p− well, n− well, twin-tub (n− and p− wells), and the like. Although n-channel embodiments are described above, p-channel embodiments may be implemented in a substantially similar manner by interchanging “p” and “n” in the above description.

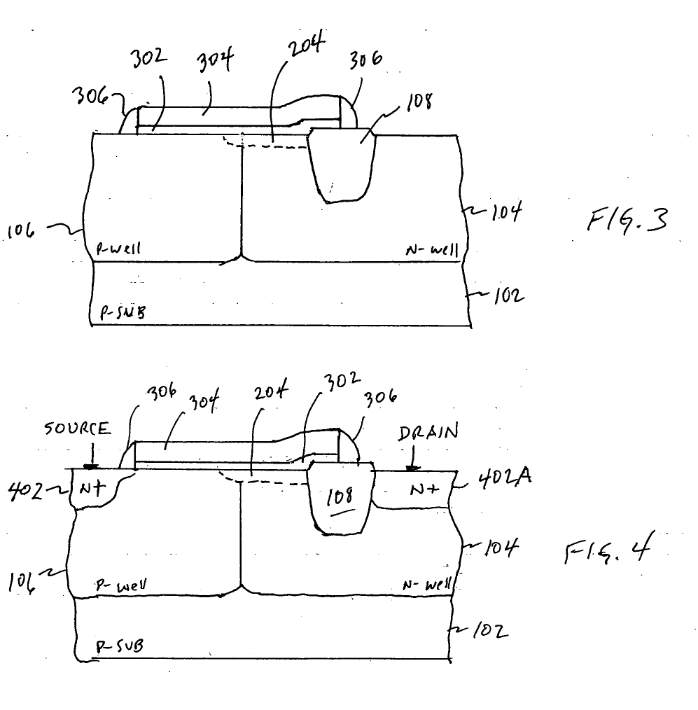

FIG. 5 illustrates a stage in the fabrication process of a graded junction LDMOS device, according to one embodiment. Embodiments of a graded-junction LDMOS device are described in the above-referenced related patent application entitled, “GRADED JUNCTION HIGH-VOLTAGE MOSFET IN STANDARD LOGIC CMOS” by Bin Wang, filed Jul. 2, 2004. In this exemplary embodiment, the LDMOS device is a n-channel device to be embedded in a standard CMOS IC. Standard structures such as a body terminal for substrate back biasing are omitted in the interest of clarity.

Starting with a p− substrate 502, a n− well 504 and a p− well 506 are formed in substrate 502. In this embodiment, wells 504 and 506 are formed in substrate 502 using standard processes for low-voltage MOS devices. However, unlike the embodiment of FIGS. 1-4, in this embodiment the wells are spaced apart to form a graded junction. In one embodiment, the separation between the wells is about 1.61 μm. In other embodiments, a separation of about 0.4 μm and greater are suitable. This region of substrate 502 between wells 504 and 506 is also referred to herein as the separation region. The separation region may be formed by forming the well regions spaced apart. In some embodiments, the separation region may have a net dopant concentration that is between those of the n− and p− wells. For example, the separation region may be doped to a n−—concentration level. In one embodiment, the separation region has the substrate doping level.

In this embodiment, an isolator 508 is then formed in n− well 504. In this embodiment, isolator 508 is formed using a suitable shallow trench isolation (STI) process. In other embodiments, isolator 508 may be a field oxide region formed using suitable processes such as a local oxidation of silicon (LOCOS) process. After this stage, this embodiment of the LDMOS fabrication process is substantially similar to that of the embodiment of FIGS. 2-4.

FIG. 6 illustrates a subsequent stage in this exemplary fabrication process of a LDMOS device. Using standard photolithography processes, a photomask 602 is formed over wells 504 and 506, defining a counter dopant implant region 604 adjacent to isolator 508 to receive a surface implant. In this exemplary embodiment, counter dopant implant region 604 is defined by photomask 602 in a non-self aligned process. As can be seen in FIG. 6, counter dopant implant region 604 extends from isolator 508 partially into the separation region.

In operation, the separation region form a graded junction that separates the p− well and n− well, which in turn increases the gated diode breakdown voltage as described in the aforementioned “GRADED JUNCTION HIGH-VOLTAGE MOSFET IN STANDARD LOGIC CMOS” patent application. In addition, counter dopant implant region 604 further increases the gated diode breakdown voltage and reduces stress to the gate oxide (formed at a later stage) as described above for the embodiment of FIGS. 1-4.

In other embodiments, the counter dopant implant region need not extend into the separation region. In still other embodiments, the counter dopant implant region may extend through the separation region and into the p-well so that it will be adjacent to the subsequently formed source contact region of the LDMOS device. In still other embodiments, the counter dopant implant region may extend into the separation region and but not into the p-well.

Further, in other embodiments, the counter dopant implant may cause the portion of the counter dopant implant region residing in the “drain” well (i.e., n− well 504 in this exemplary embodiment) to have a reduced net dopant concentration that does cause the portion to be counter doped. For example, if the “drain” well is an n− well, then in such an embodiment the portion of the counter dopant implant region (which may be the entire counter dopant implant region in some embodiments) remains of n-type conductivity, but of a lower net concentration of n-type dopants than the n− well.

Further, in accordance with this embodiment, the counter dopant implant is the same implant that is used to adjust the Vt of the standard low-voltage devices in the IC. Photomask 602 is formed in the same photomask processes used to form the Vt adjust implant mask. Thus, in this embodiment, no additional implants or photolithography processes are needed.

FIG. 7 illustrates another stage in this exemplary fabrication process of a LDMOS device. In this exemplary process, standard processes used in forming a gate oxide, a gate, and end caps for the low voltage MOS devices are also used to form a gate oxide 702, a gate 704, and end caps 706 of the LDMOS device. Thus, no additional steps are needed to form these structures for the LDMOS device.

FIG. 8 illustrates another stage in this exemplary fabrication process of a LDMOS device. In this exemplary process, n+regions 802 and 802A are formed in wells 506 and 504, respectively. These n+regions serve as source/drain contact regions for subsequent metal (or other conductor) deposition processes. In one embodiment, standard n-type dopant implantation processes are used to form n+regions 802 and 802A at the same time that the source/drain regions of the low voltage MOS devices of the IC are formed. Thus, no additional process steps are needed to form the source/drain regions of the LDMOS device. Additional processes are then performed to form interconnect between the LDMOS device to other devices or structures in the IC.

This exemplary fabrication process may be implemented in other MOS process such as, for example, p− well, n− well, twin-tub (n− and p− wells), and the like. Although n-channel embodiments are described above, p-channel embodiments may be implemented in a substantially similar manner by interchanging “p” and “n” in the above description.

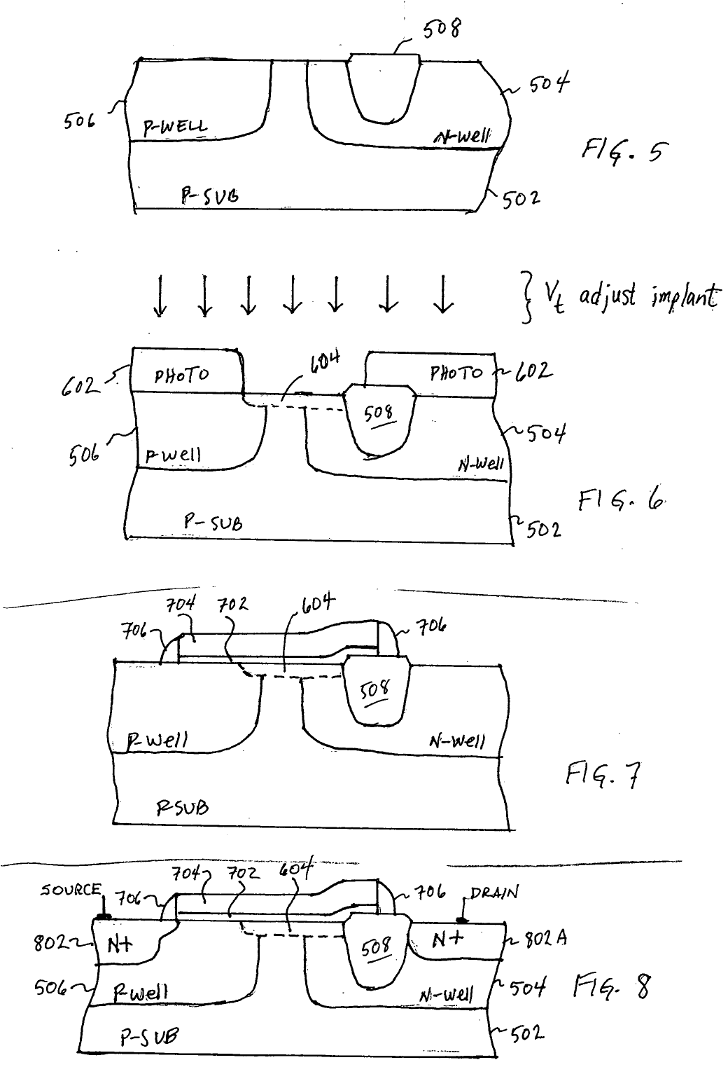

FIG. 9 illustrates a stage in the fabrication of a LDMOS device 900 according to another embodiment. This embodiment is substantially similar to the embodiment described above in conjunction with FIGS. 1-4 except that counter dopant implant region extends under the entire gate of the LDMOS device.

In this embodiment, LDMOS device 900 is formed on a p− substrate 902. A n− well 904 and a p− well 906 are formed in substrate 902 so that they are adjacent as previously described. In other embodiments, a separation region may be formed between n− well 904 and p− well 906.

An isolator 908 is formed in n− well 904. In one embodiment, isolator 908 is formed as described for previous embodiments. A counter dopant implant region 914 is then formed in n− well 904 adjacent to isolator 908, extending relatively far into p− well 906 (compared counter dopant implant region 204 of FIG. 2). In one embodiment, counter dopant implant region 914 is formed using p-type dopants as described for the counter dopant implant regions of the previous embodiments. In particular, in accordance with this embodiment, counter dopant implant region is formed using the Vt implantation that is already required for other devices being fabricated on the same IC as LDMOS device 900. Thus, no additional process steps are required to form counter dopant implant region 914 relative to those needed to fabricate standard low-voltage MOS devices on the IC.

A gate oxide 922, gate 924 and end caps 926 are then formed on wells 904 and 904, and partially on isolator 908. In one embodiment, these structures are formed as described above for the previous embodiments.

A n+region 932 and a n+region 932A are formed in wells 906 and 904, respectively. These regions serve as a source contact and a drain contact, respectively. In one embodiment, these structures are formed as described above for the previous embodiments.

This embodiment operates in substantially the same manner as the embodiment of FIGS. 1-4, with. When the implant that counter dopes the drain region extending into the channel region, the dopant adds to the channel concentration rather than counter doping it as happens in the drain region. The additional channel doping cause the Vt of the device to increase.

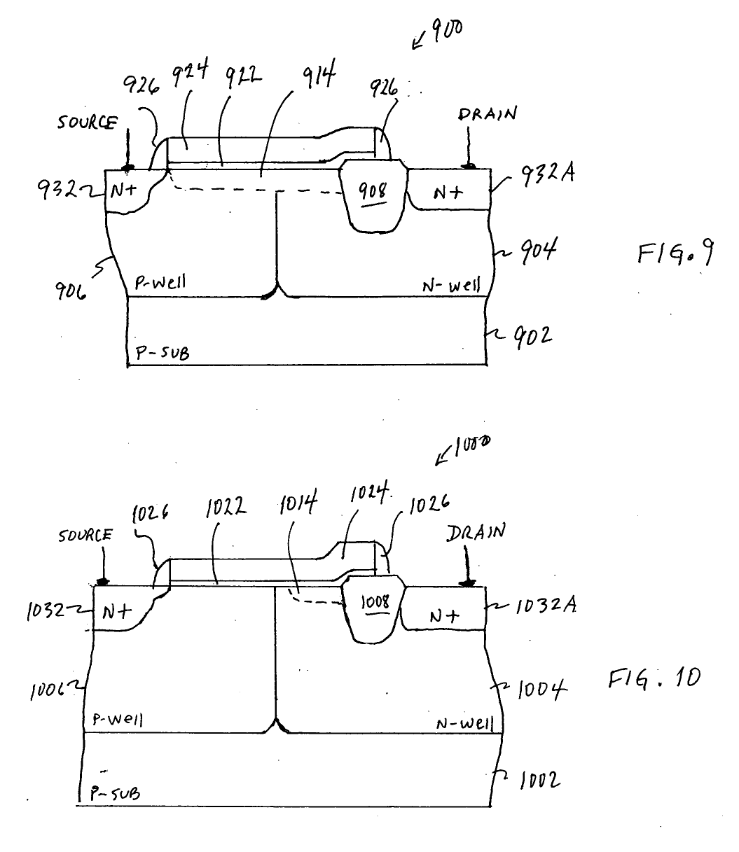

FIG. 10 illustrates a stage in the fabrication of a LDMOS device 1000 according to another embodiment. This embodiment is substantially similar to the embodiment described above in conjunction with FIGS. 1-4 except that counter dopant implant region is contained entirely within the n-well.

In this embodiment, LDMOS device 1000 is formed on a p- substrate 1002. A n− well 1004 and a p− well 1006 are formed in substrate 1002 so that they are adjacent as previously described. In other embodiments, a separation region may be formed between n− well 1004 and p− well 1006.

An isolator 1008 is formed in n− well 1004. In one embodiment, isolator 1008 is formed as described for previous embodiments. A counter dopant implant region 1014 is then formed in n− well 1004 adjacent to isolator 1008, entirely within n− well 1004. In one embodiment, counter dopant implant region 1014 is formed using p-type dopants as described for the counter dopant implant regions of the previous embodiments.

A gate oxide 1022, gate 1024 and end caps 1026 are then formed on wells 1004 and 1004, and partially on isolator 1008. In one embodiment, these structures are formed as described above for the previous embodiments.

A n+region 1032 and a n+region 1032A are formed in wells 1006 and 1004, respectively. These regions serve as a source contact and a drain contact, respectively. In one embodiment, these structures are formed as described above for the previous embodiments.

This embodiment operates in substantially the same manner as the embodiment of FIGS. 1-4, with no increase of the channel doping, resulting in a device with a lower Vt.

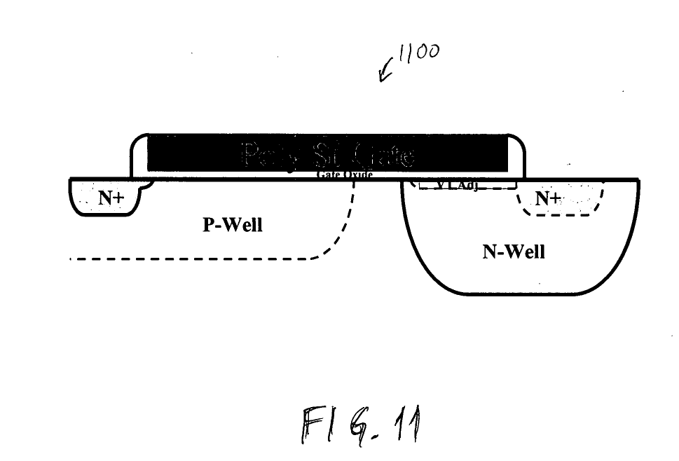

FIG. 11 illustrates a stage in the fabrication of a LDMOS device 1100 without an isolator in the drain well, according to one embodiment. In this embodiment, LDMOS device 1100 is substantially the same as the embodiment of FIGS. 5-8 having a separation region, except that isolator 508 is omitted and the counter dopant implant region does not extend into the separation region. In other embodiments, the counter dopant implant region may extend into the separation region or even into the p− well. In some applications, sufficient voltage drop between the n+drain contact region and the gate is achieved by the counter dopant region without having the current flow directed below an isolator structure. The LDD and/or source/drain extension implants are blocked on the drain side of this device, resulting in only the source region having an extension. In other embodiments (not shown), the n+ source/drain implant is not adjacent to the gate endcap.

In addition, embodiments of the present invention may be implemented not only with physical components (e.g., within a semiconductor chip), but also within machine-readable media. For example, the designs described above may be stored upon and/or embedded with machine readable media associated with a design tool used for designing semiconductor devices. Examples include designs defined/formatted in VHSIC Hardware Description Language (VHDL), Verilog language and SPICE language. Some netlist examples include: a behavior level netlist, a register transfer level (RTL) netlist, a gate level netlist, and a transistor level netlist. Machine readable media also include media having layout information such as a GDS-II file. Further, netlist files or other machine-readable media for semiconductor chip design may be used in a simulation to perform the methods of the embodiments disclosed herein.

Thus, embodiments of the present invention may be used as or to support software program executed upon some form of processing core (e.g., a CPU of a computer) or otherwise implemented or realized upon or within a machine-readable medium. A machine-readable medium includes any mechanism for storing or transmitting information in a form readable by a machine (e.g. a computer). For example, a machine-readable medium can include read only memory (ROM), random access memory (RAM), magnetic disk storage media, optical storage media, flash memory devices, etc. In addition, machine-readable media can include propagated signals such as electrical, optical, acoustical or other form of propagated signal (e.g., carrier wave signals, infrared signals, digital signals, etc.) One skilled in the relevant art may recognize, however, that the invention may be practiced without one or more of the specific details, or with other methods, resources, materials, etc. In other instances, well known structures, resources, or operations have not been shown or described in detail merely to avoid obscuring aspects of the invention.

While example embodiments and applications have been illustrated and described, it is to be understood that the invention is not limited to the precise configuration and resources described above. Various modifications, changes, and variations apparent to those skilled in the art may be made in the arrangement, operation, and details of the methods and systems of the present invention disclosed herein without departing from the scope of the claimed invention.

What is claimed is:

1. A n-channel field effect transistor, comprising:
a p type substrate;
a p− well disposed in said substrate;
a first n+ doped region disposed in said p− well;
a first terminal coupled to said first n+ doped region;
an n− well disposed in said substrate;
a second n+ doped region disposed in said n− well;
a second terminal coupled to said second n+ doped region;
a gate oxide layer disposed over at least a portion of: said p− well, and said n− well;
a gate disposed over at least a portion of said gate oxide layer; and
a counter dopant region with at least a portion disposed in said n− well between said second n+ doped region and said p= well.

2. The transistor of claim 1 wherein a portion of said counter dopant region is disposed outside of said n− well.

3. The transistor of claim 1, further comprising a graded-junction region of said substrate separating said p− well and said n− well.

4. The transistor of claim 3, wherein an implant used to form said counter dopant region also implants dopants into said graded-junction region.

5. The transistor of claim 3, wherein said counter dopant region within said n− well does not form a counter-doped region in said n− well but reduces a net n doping of said n− well.

6. The transistor of claim 3, wherein the counter dopant region within said n− well forms a counter-doped region in said n− well.

7. The transistor of claim 1, further comprising an isolator formed in said n− well between said second n+ region and said counter dopant region, a portion of said gate being formed on a portion of said isolator, wherein said isolator is formed using a shallow trench isolation (STI) process.

8. The transistor of claim 1, further comprising an isolator formed in said n− well between said second n+region and said counter dopant region, a portion of said gate being formed on a portion of said isolator, wherein said isolator is formed using a local oxidation of silicon (LOCOS) process.

9. The transistor of claim 1 wherein the counter dopant region is formed using an implant that is also used to adjust a threshold voltage of a low-voltage field effect transistor being fabricated on the substrate.

10. The transistor of claim 9 wherein a portion of said counter dopant region is disposed proximate to said first n+ doped region.

11. A p-channel field effect transistor, comprising:
a n type substrate;
a n− well disposed in said substrate;
a first p+ doped region disposed in said p− well;
a first terminal coupled to said first p+ doped region;
an p− well disposed in said substrate;
an isolator disposed in said p− well;
a counter dopant region with at least a portion disposed in said n− well between said first isolator and said n− well;
a second p+ doped region disposed in said n− well;
a second terminal coupled to said second p+ doped region;
a gate oxide layer disposed over at least a portion of: said n− well, said p− well, and said isolator; and
a gate disposed over at least a portion of said gate oxide layer.

12. The transistor of claim 11 wherein a portion of said counter dopant region is disposed outside of said p− well.

13. The transistor of claim 11, further comprising a graded-junction region of said substrate separating said p− well and said n− well.

14. The transistor of claim 13, wherein an implant used to form said counter dopant region also implants dopants into said graded-junction region.

15. The transistor of claim 13, wherein said counter dopant region within said p− well does not form a counter-doped region in said p− well but reduces a net p doping of said p− well.

16. The transistor of claim 13, wherein the counter dopant region within said p− well forms a counter-doped region in said p− well.

17. The transistor of claim 11 wherein the counter dopant region is formed using an implant that is also used to adjust a threshold voltage of a low-voltage field effect transistor being fabricated on the substrate.

18. The transistor of claim 17 wherein a portion of said counter dopant region is disposed proximate to said first p+ doped region.

19. A non-self aligned laterally diffused metal oxide semiconductor (LDMOS) device comprising a source, drain, gate, substrate and counter dopant region, wherein the drain includes a well implant region of opposite polarity to that of the substrate and a drain contact region disposed in the well implant region, the drain extending under the gate, and wherein the counter dopant region has at least a portion disposed in the Well implant region between the drain contact region and the source.

19. The non-self aligned LDMOS device of claim 19 further comprising an isolator disposed in the well implant region between the drain contact region and the counter dopant region.

20. The non-self aligned LDMOS device of claim 19 further comprising an graded junction region between the source and Well implant region.

21. The non-self aligned LDMOS device of claim 19 wherein the counter dopant region is contained within the Well implant region.

22. A method of fabricating a field effect transistor, comprising:
forming a p− well in a substrate;
forming an n− well in said substrate;
forming a gate oxide layer over at least a portion of: said p− well, said graded junction region, and said n− well;
forming a gate disposed over at least a portion of said gate oxide layer; and
forming a first n+ doped region in said p− well and a second n+ doped region in said n− well; and
forming a counter dopant region with at least a portion disposed in said n− well between said second n+ doped region and said p− well;

23. The method of claim 21, further comprising forming a graded-junction region in said substrate between said p− well and said n− well.

24. The method of claim 23, wherein the graded-junction region is formed by forming said p− well and said n− well so that said p− well spaced is apart from said n− well

25. The method of claim 23, wherein said counter dopant region extends into said graded-junction region.

26. The method of claim 23, wherein said counter dopant region within said n− well does not form a counter-doped region in said n− well but reduces a net n doping of said n− well.

27. The method of claim 23, wherein the counter dopant region within said n− well forms a counter-doped region in said n− well.

28. The method of claim 21, further comprising forming a plurality of MOS devices in said substrate.

29. The method of claim 28 wherein the counter dopant region is formed using an implant that is also used to adjust a threshold voltage of the plurality of MOS devices.

30. The method of claim 29 wherein a portion of said counter dopant region is disposed proximate to said first n+ doped region.

31. The method of claim 21 further comprising forming an isolator in said n− well between said counter dopant region and said second n+ doped region, wherein a portion of said gate is disposed on a portion of said isolator.
